(19) United States
(12) Patent Application Publication
(10) Pub. No.: US 2016/0149060 A1
(43) Pub. Date: May 26, 2016

(54) Light Receiving Device

(71) Applicant: University of Surrey, Surrey (GB)

(72) Inventors: Stephen Sweeney, Surrey (GB); Konstanze Hild, Surrey (GB)

(73) Assignee: University of Surrey, Surrey (GB)

(21) Appl. No.: 14/900,094

(22) PCT Filed: Jun. 19, 2014
(86) PCT No.: PCT/GB2014/051879

§ 371 Date: Dec. 18, 2015

(30) Foreign Application Priority Data
Jun. 19, 2013 (GB) 1310954.1

(51) Int. Cl. H01L 31/0304; H01L 31/06; H01L 31/18

(52) U.S. Cl. CPC H01L 31/03044; H01L 31/1856; H01L 31/06

(57) ABSTRACT

A photovoltaic device having an active region comprising a III-V material including Bismuth and one or more other group V elements, the band gap energy of the material is in the range of from 0.4 to 1.4 eV and the spin-orbit splitting energy of the material is in the range of from 0.3 to 0.8 eV.

The present invention relates to a light receiving device. More particularly, the present invention relates to a photodetector and a solar cell.

There is strong interest in renewable energy, and in particular, in harnessing energy from the sun. One of the possibilities to do this is the use of photovoltaic modules. The majority of currently available commercial solar cells are based on silicon as this is widely available and relatively inexpensive to manufacture. In general, silicon is a relatively poor material for photonic applications owing to the fact that it is a so-called “indirect” band gap semiconductor meaning that optical transitions are relatively weak. Also, as an elemental semiconductor, there is little or no scope to tailor the crystal structure to provide a more optimum overlap with the solar spectrum.

As a consequence, silicon-based solar cell module efficiencies have remained relatively static over the past 20 years with efficiencies hovering around 20% under the global AMi.5 spectrum (1 kW/m²) with reports of up to 25% for small lab-scale cells. Other approaches include thin-film chalcogenide based cells, with efficiency reports of 19.6% efficiency for small CIGS based cells on glass substrates and around 17% for larger modules.

Organic based solar cells are also emerging as an inexpensive alternative route to produce large area panels. Laboratory efficiencies of up to 11.1% have been reported for small (<o.2 cm²) cells and 7% for larger modules.

Broadly speaking, there are two approaches to develop solar cells both of which aim to reduce the cost of power generation ($/Watt). One such approach is to create cheap large area, lower efficiency cells (such as the chalcogenide, organic and amorphous silicon approaches) and the other is to create higher cost but significantly higher efficiency solar cells. In this latter category, compound semiconductors are leading the way with a verified record efficiency of 28.8% for small GaAs-based thin-film cells and 24.1% for GaAs-based modules.

For a single absorbing layer (singlejunction) solar cell, the Shockley Queisser limit, first derived in 1961 defines the maximum possible efficiency under solar illumination based on a detailed balance approach. According to this limit, a maximum efficiency of 33.7% is imposed on a single junction cell with a band gap in the i.1-i.4 eV range. This, together with reduced non-radiative recombination and a direct band gap largely explains the success of GaAs compared to silicon. However, to go beyond this limit requires alternative approaches, for example through the development of multi-junction solar cells, whereby multiple semiconductor layers of different band gaps are used to capture different parts of the solar spectrum.

InGaP/GaAs/InGaAs triple junction cells have had reported efficiencies of 37.7% under normal solar illumination for a InGaP/GaAs/InGaAs triple junction cell. The current record solar cell efficiency stands at 44.0% at a concentration of 942 suns. This is based upon a multi junction cell geometry including a so-called dilute-nitride layer targeting the 1 eV band gap. These are still somewhat lower than the theoretical maximum efficiency of 56% expected for a triple junction cell under normal solar illumination.

Limiting factors in multijunction cell design relate to difficulties in producing high quality lattice-matched semiconductor layers and the need to balance the current generation in each junction.

Other approaches to further improve efficiency include the development of higher numbers ofjunctions in a cell to provide even better match to the solar spectrum, where for example, an efficiency of 70% is predicted for an 8 junction cell. However, the added complexities involved in achieving this from a material quality and current balancing perspective make this a very challenging proposition.

Hot carrier or quantum dot approaches forming “intermediate band” solar cells have gained interest. In such structures an intermediate band material is used as the absorber in a single junction cell. In such a material, sub-band gap photons are absorbed via the intermediate band in addition to transitions directly across the band gap. The two generated currents combine without the current balancing issues of multi-junction cells. Quantum dots offer a route to achieving the intermediate band effect by exploiting the quantum dot energy levels. Efficiencies of i8% have been achieved with this approach based upon In(Ga)As/GaAs quantum dots. The efficiency of these devices is limited by non-radiative recombination and a reduced open-circuit voltage.

In addition to solar cells, photodetectors use semiconductor materials to detect light. For example, InGaAs photodiodes can be used to detect infrared light.

The present invention sets out to provide a light receiving devices such as photodetectors and solar cells with improved performance compared to conventional arrangements.

According to a first aspect of the invention there is provided a photovoltaic device having an active region comprising a III-V material including Bismuth and one or more other group V elements, the band gap energy of the material is in the range of from 0.4 to 1.4 eV and the spin-orbit splitting energy of the material is in the range of from 0.3 to o.8 eV.

As a result, the efficiency of such a photovoltaic device will be increased compared to conventional solar cells by maximising the wavelengths of solar light absorbed by the cell. Such embodiments can enable a single layer of III-V material to absorb significant visible light via the spin-orbit splitting energy of the material and the band gap. By varying the amount of Bi, it is possible to tune the single layer of III-V material to different parts of the visible spectrum.

It will be appreciated that in a conventional semiconductor active material for a solar cell, the open-circuit voltage (i.e. the maximum voltage available from the solar cell) is related to the band gap Eg. However, for solar cells according to the invention, by using absorption from the spin-orbit splitting energy of the material, the the open-circuit voltage can exceed the band gap Eg.

In some embodiments, the III-V material includes Ga and As.

In some embodiments, the percentage of atoms of Bismuth to atoms of the other group V elements in the material is less than 1i.5%.

In some embodiments, the III-V material comprises a Ga—As—Bi based material, having Formula 1:

GaAS1-xBix [Formula 1]

wherein o:::;x:::; o.15

In some embodiments, the band gap of the active material is in the range of from approximately 1 to 1.1 eV and the spin-orbit splitting energy of the material is in the range of from o.6 to 0.7 eV, and o.05:::;x:::;o.07.

In some embodiments, the III-V material comprises a GaAsBiN based material.

In some embodiments, the band gap of the active material is in the range of from approximately o.8 to 14 eV and the spin-orbit splitting energy of the material is in the range of from 0.3 to o.8 eV.

In some embodiments, the GaAsBiN based material includes less than 10% Bi and less than 6% Ni based on the amount of As, optionally wherein the GaAsBiN based material includes from 2 to 4% Bi and from 0.5 to i.5% Ni based on the amount of As.

In some embodiments, the III-V material is grown on a GaAs or Ge substrate. Hence, such embodiments of the invention provide a new semiconductor material system that has significant benefits for increasing the efficiency of solar cells. The material system is compatible with GaAs and can therefore be manufactured using conventional semiconductor fabrication methods.

In some embodiments, the III-V material comprises a GainAsBi based material.

In some embodiments, the GainAsBi based material includes less than 5% Bi and In ranging from 30 to 60% based on the amount of As.

In some embodiments, the GainAsBi based material is grown on a InP substrate.

According to a another aspect of the invention there is provided a photovoltaic device having an active region comprising a III-V material including Antimony and one or more other group V elements, the band gap energy of the material is in the range of from 0.4 to 1.4 eV and the spin-orbit splitting energy of the material is in the range of from 0.3 to o.8 eV.

In some embodiments, the percentage of atoms of Antimony to atoms of the other group V elements in the material is less than 25%, and wherein the III-V material includes Ga and As.

In some embodiments, the III-V material forms the active region of a single junction cell or one junction of a multijunction cell.

According to a another aspect of the invention there is provided a light receiving semiconductor device having an active region comprising a III-V material including Bismuth and one or more other group V elements, such that the spin-orbit splitting energy of the material is within 10% of the band gap energy of the material.

The efficiency of a photodetector is typically measured by how well the photodetector absorbs one particular wavelength or range of wavelengths. Hence, a light receiving semiconductor device according to such an embodiment will be highly efficient.

In some embodiments, the percentage of atoms of Bismuth to atoms of the other group V elements in the material is less than 1i.5%.

In some embodiments, the III-V material includes Ga and As

In some embodiments, the spin-orbit splitting energy of the material is within 10% of the band gap energy of the material.

In some embodiments, the spin-orbit splitting energy of the material is substantially equal to the band gap energy of the material.

In some embodiments, the spin-orbit splitting energy is in the range of from 0.3 to 1.0 eV.

In some embodiments, the III-V material comprises a Ga—As—Bi based material, having Formula 1:

GaAs₁₋ₓBiₓ [Formula 1]

wherein the spin-orbit splitting energy of the material is in the range of from o.7 to 0.9 eV, and o.09:::;x:::;o.11,

In some embodiments, the III-V material comprises a GaAsBiN based material.

In some embodiments, the band gap of the active material is in the range of from approximately 0.3 to 0.9 eV, and the GaAsBiN based material includes 3 to 10% Bi and less than 6% Ni based on the amount of As, optionally wherein the GaAsBiN based material includes from 2 to 4% Bi and from 0.5 to i.5% Ni based on the amount of As, optionally 5 to 7% Bi and 2 to 4% Ni based on the amount of As.

In some embodiments, the III-V material is grown on a GaAs or Ge substrate.

In some embodiments, the III-V material comprises a GainAsBi based material.

In some embodiments, the GainAsBi based material includes 2 to 4% Bi and In ranging from 51 to 55% based on the amount of As, and having a spin-orbit splitting energy in the range of from 0.5 to o.6 eV.

In some embodiments, the GainAsBi based material is grown on a InP substrate.

According to another aspect of the invention, there is provided a light receiving semiconductor device having an active region comprising a III-V material including Antimony and one or more other group V elements, such that the spin-orbit splitting energy of the material is within 10% of the band gap energy of the material, optionally within 5% of the band gap energy of the material.

In some embodiments, the percentage of atoms of Antimony to atoms of the other group V elements in the material is less than 25%, and wherein the III-V material includes Ga and As.

According to another aspect of the invention there is provided a light receiving semiconductor device having an active region comprising a III-V material including Bismuth and one or more other group V elements, such that the amount of Bismuth is controlled so as to produce a band gap energy of the material appropriate for absorbing light at the first wavelength and to produce a spin-orbit splitting energy of the material capable of absorbing light at the second wavelength.

The first wavelength and the second wavelength could be tuned to be different or substantially similar, depending on the application.

For a solar cell, it would be desirable to choose the first wavelength and the second wavelength at appropriate points in the visible spectrum. For a thermo-photovoltaic, it would be desirable to choose the first wavelength and the second wavelength at appropriate points in the infrared. For a photodector, it may be desirable to choose the first wavelength and the second wavelength to be substantially equal.

According to another aspect of the invention there is provided a method of manufacturing a light receiving semiconductor device arranged to absorb light at a first wavelength and a second wavelength, the method comprising: providing an active layer comprising a III-V material including Bismuth and one or more other group V elements; controlling the amount of Bismuth in the III-V material so as to produce a band gap energy of the material appropriate for absorbing light at the first wavelength and to produce a spin-orbit splitting energy of the material capable of absorbing light at the second wavelength.

According to another aspect of the invention there is provided a light receiving semiconductor device having an active region comprising a III-V material including Antimony and one or more other group V elements, such that the amount of Antimony is controlled so as to produce a band gap energy of the material appropriate for absorbing light at the first wavelength and to produce a spin-orbit splitting energy of the material capable of absorbing light at the second wavelength.

According to a another aspect of the invention there is provided a method of manufacturing a light receiving semiconductor device arranged to absorb light at a first wavelength and a second wavelength, the method comprising: providing an active layer comprising a III-V material including Antimony and one or more other group V elements; controlling the amount of Antimony in the III-V material so as to produce a band gap energy of the material appropriate for absorb light at the first wavelength and to produce a spin-orbit splitting energy of the material capable of absorbing light at the second wavelength.

### Embodiments of the invention will now be described, by way of example and with reference to the accompanying drawings in which:

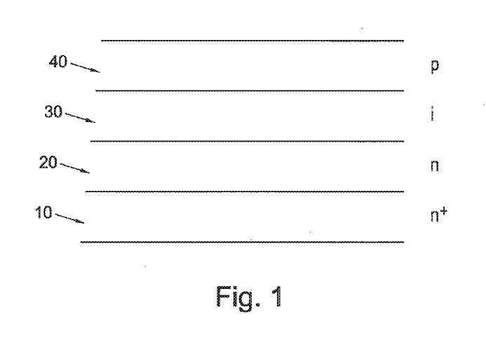

FIG. 1 shows a schematic of a single junction solar cell according to a first embodiment of the invention;

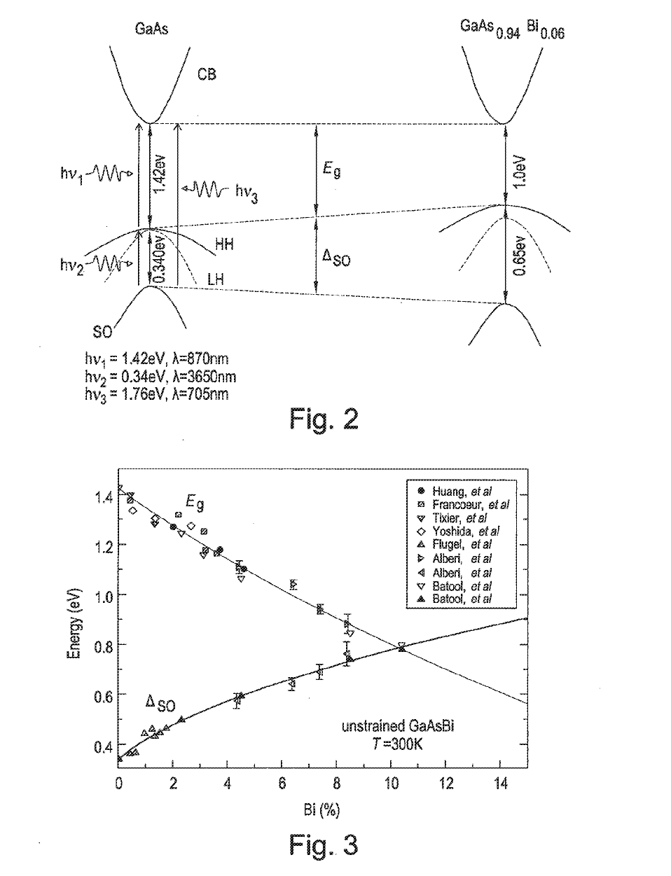

FIG. 2 shows a schematic comparison of the band gap structure of a conventional GaAs active region, compared to the band gap structure of an active region comprising GaAso.₉₄Bio.o6 according to the present invention;

FIG. 3 shows a graph of the relationship between the spin-orbit splitting energy (LiSO) and the band gap (Eg) of GaAsl-xBix as a function of Bi concentration;

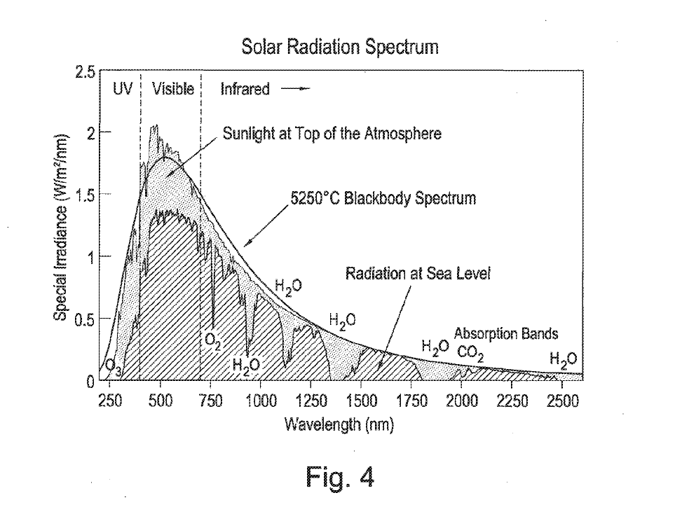

FIG. 4 shows a graph of the solar radiation spectrum;

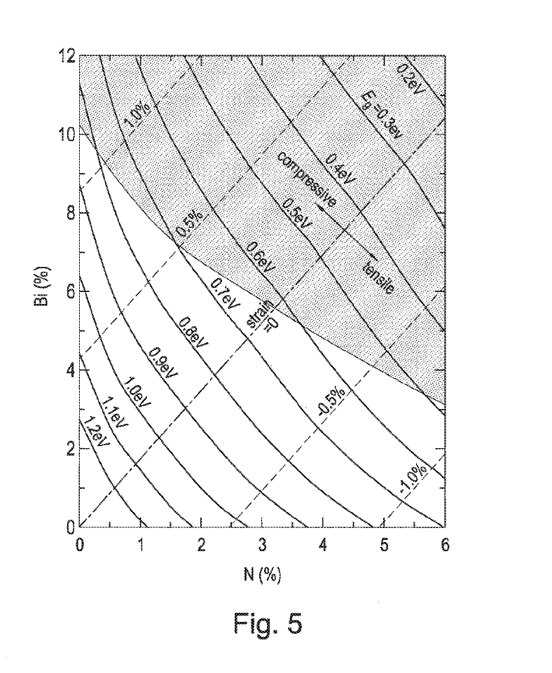

FIG. 5 shows the predicted band gap of GaAsBiN on GaAs as a function of Bi and compositions at 300 K;

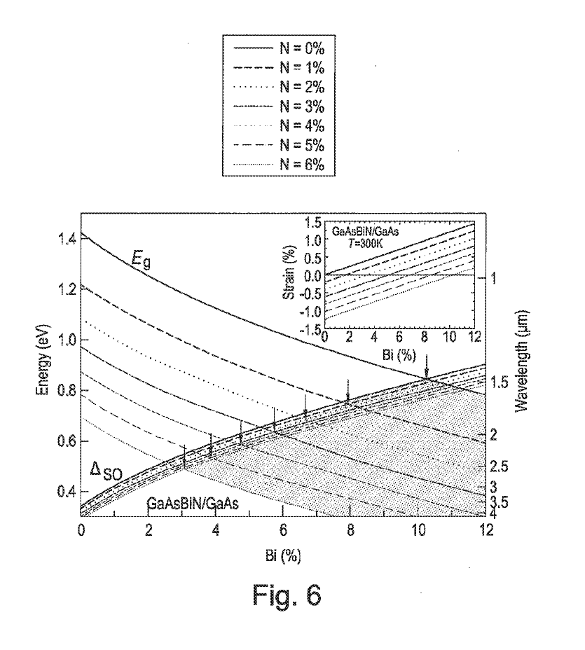

FIG. 6 shows the predicted band gap and spin-orbit splitting energy as a function of Bi and N compositions in GaAsBiN on GaAs at 300 K;

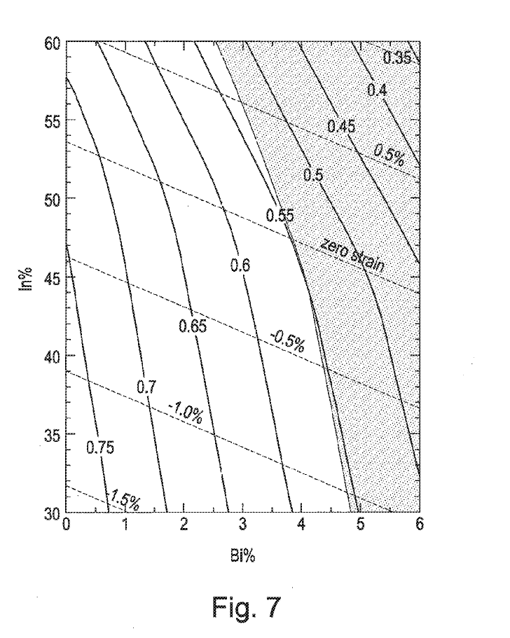

FIG. 7 shows the predicted band gap of GainAsBi on InP as a function of Bi and In compositions at 300 K;

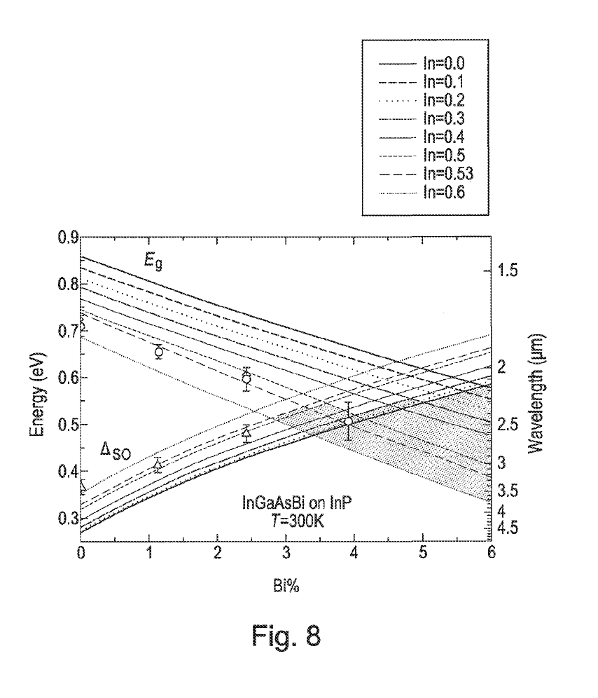

FIG. 8 shows the predicted band gap and spin-orbit splitting energy as a function of Bi and In compositions in GainAsBi on InP at 300 K.

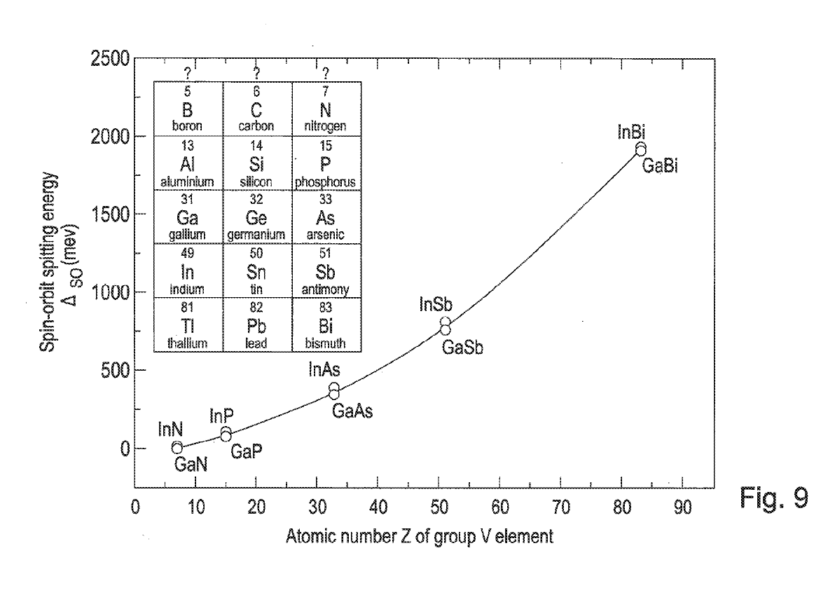

FIG. 9 shows the predicted variation in spin-orbit splitting energy as a function of group V atomic number for III-V compounds.

FIG. 1 shows a schematic of a single junction solar cell 1 according to a first embodiment of the invention. The solar cell 1 comprises an n+ type GaAs substrate 10, a n type GaAs buffer layer 20, an i type GaAsBi based material photovoltaic layer 30, and a p+ type GaAs capping layer 40.

In this embodiment, the n+ type GaAs substrate 10 is doped with Si at a concentration of 4×10¹⁸ cm² and the n type GaAs buffer layer 20 is doped with Si at a concentration of 1×10 ¹⁸ cm², with the n type GaAs buffer layer 20 having a thickness of 200 nm. In other embodiments, other dopants could be used.

In this embodiment, the i type GaAsBi based material photovoltaic layer 30 comprises a layer of undoped GaAso.₉₄Bio.o6 at a thickness of 500 nm. In other embodiments, thicknesses of, for example, 200 nm to 5 μm could be used.

The p+ type GaAs capping layer 40 has a thickness of 100 nm, and doped with Be at a concentration of 8×10¹⁸ cm². In other embodiments, other dopants could be used.

As a result, FIG. 1 shows a solar cell having an active region comprising GaAso.₉₄Bio.o6. The properties of such an active region are shown in FIG. 2, which shows a schematic comparison of the band gap structure of a conventional GaAs active region, compared to the band gap structure of an active region comprising GaAso.₉₄Bio.o6 according to the present invention. FIG. 3 shows a graph of the relationship between the spin-orbit splitting energy (L1SO) and the band gap (Eg) of GaAsl-xBix as a function of Bi concentration. FIG. 4 shows a graph of the solar radiation spectrum.

Due to the large mass of bismuth atoms, the incorporation of bismuth leads to a large increase in the spin-orbit splitting energy L1SO, as illustrated in FIG. 3.

The left hand side of FIG. 2 shows an example of possible absorption transitions in bulk GaAs at room temperature. A semiconductor such as GaAs has a conduction band CB and a valence band separated by a band gap Eg of 1.42 eV at 300K.

The valence band has a fine structure and is split into a heavy hole band HH, a light hole band LH and a spin-orbit band SO. The difference in energy between the top of the heavy hole band HH and the top of the spin orbit band SO is the spin-orbit splitting energy L1So, which for bulk GaAs is 0.340 eV at 300K.

Although not widely considered, it will be appreciated from FIG. 2 that in a material such as bulk GaAs, there are three main mechanisms by which a photon can be absorbed.

It will be appreciated that a photon of wavelength approximately 87 onm (hv1) can cause an electron to move from the HH band to the CB, such a photon has a wavelength corresponding to the band gap Eg of GaAs.

However, it is also possible that a photon can sequentially cause an electron to move from the SO band to the HH band, or from the SO band to the conduction band CB. It will be appreciated that the transition from SO to HH can only happen if there are empty states available, i.e. if a photon has already been absorbed across the band gap creating holes in the HH band. As clear from FIG. 2, the SO-HH transition requires a photon of wavelength of approximately 3650 nm (hv2), which the SO-CB transition requires a photon of wavelength of approximately 705 nm (hv3).

It will be appreciated that the absorption mechanism for the HH-CB transition (i.e. across the band gap Eg) is stronger than for the SO-HH transition (i.e. across L1SO) or for the SO-CB transition (i.e. across Eg(SO)). In other words, HH-CB absorption is inherently more efficient than SO-HH or SO-CB absorption Furthermore, SO-HH absorption occurs sequentially after HH-CB absorption since it requires an available hole state in the HH band.

Hence, for bulk GaAs, there could be absorption at approximately 87 onm (hv1), approximately 3650 nm (hv2), and approximately 705 nm (hv3).

Wavelengths 870 nm (hv1) and 705 nm (hv3) are relatively close to the peak of the solar spectrum. However as discussed, the SO-HH transition (i.e. corresponding to the gap L1SO) is also a potentially strong absorption transition at 3650 nm (hv2), which is far into the mid-infrared where there is very little solar radiation (see FIG. 4).

As a result, solar cells that use conventional GaAs active materials do not make use of the SO-HH transition (i.e. corresponding to L1SO).

The right hand side of FIG. 2 provides a schematic of the band structure of GaAso.94Bio.06.

In this case, as for bulk GaAs, absorption can occur as a result of the HH-CB transition (i.e. across the band gap Eg), the SO-HH transition (i.e. across L1SO) or the SO-CB transition. Similarly, the HH-CB absorption is inherently more efficient than SO-HH or SO-CB absorption.

However, as can be seen, the addition of Bi (see FIG. 3) has changed the energetic positions of the band gap Eg and L1SO for GaAso.₉₄Bio.o6 as compared to GaAs. Advantageously for a solar cell, the addition of 6% Bi (when compared to the amount of As) changes the band gap Eg to be around 1 eV and the level of the spin-orbit splitting energy L1SO to be around 0.65 eV.

Hence, for GaAso.₉₄Bio.o6, there can be absorption at approximately 1240 nm (hv1), approximately 1937 nm (hv2), and approximately 756 nm (hv3).

As a result, the HH-CB (hv1) transition energy is around 1 eV, the target band gap for the third junction in multi junction solar cells. In addition, when compared to GaAs the SO-CB (hv3) transition has changed only slightly, and corresponds to a wavelength of 756 nm, close to the solar spectrum peak. However, the SO-HH (hv2) transition energy is approximately double that of GaAs and corresponds to absorption at approximately 1937 nm, thereby capturing a significantly higher fraction of the near-infrared tail of the solar spectrum.

This essentially means that a system using GaAso.₉₄Bio.o6 as the active material for a solar cell will provide a higher efficiency when compared to a system using conventional GaAs as the active material.

Furthermore, the fact that electrons are absorbed from the SO-band means that the open-circuit voltage, normally a limiting factor for solar cells, can be increased above the theoretical limit (i.e. above the band gap energy) and this provides a clear mechanism to exceed conventional efficiency limits in solar cells.

It will be appreciated that in a conventional semiconductor active material for a solar cell, the open-circuit voltage (i.e. the maximum voltage available from the solar cell) is related to the band gap Eg. However, for materials such as GaAso.₉₄Bio.o6, the fact that electrons are absorbed from the SO-HH means that the open-circuit voltage, normally a limiting factor for solar cells can be increased above the band gap Eg.

As a result, materials such as GaAso.₉₄Bio.o6 can provide active materials for solar cells with both higher light absorbing efficacy and higher open-circuit voltages than conventional materials. Since the absorption occurs in one layer, and essentially in parallel, the photocurrents essentially add, overcoming the current limiting issue in conventional tandem or multi junction solar cells.

In addition, a solar cell using GaAso.₉₄Bio.o6 as the active material can use conventional manufacturing techniques. As shown in FIG. 1, the substrate is GaAs, and hence manufacture of such embodiments could be very similar to the manufacture of conventional GaAs solar cells. In some embodiments, the GaAso.₉₄Bio.o6 active material could be grown on a Ge substrate which is frequently used as the bottom cell in multi-junction solar cells.

Hence, such embodiments of the invention provide a new semiconductor material system that has significant benefits for increasing the efficiency of solar cells. The material system is compatible with GaAs and can therefore be manufactured using conventional semiconductor fabrication methods.

FIG. 1 merely one configuration of a solar cell using as GaAso.₉₄Bio.o6 the active material. It will be appreciated that such an active material could be used in any suitable solar cell configuration, either as a single junction cell or as part of a multijunction cell.

While the embodiment discussed above uses GaAso.₉₄Bio.o6 as the active material, it will be appreciated that other embodiments could use other Ga—As—Bi based materials, for example with Formula 1:

GaAs₁₋ₓBiₓ [Formula 1]

As shown in FIG. 3, varying the amount of Bi, changes the levels of the band gap Eg and the spin-orbit splitting energy L1SO.

For a solar cell, it is desirable to match the band gap Eg and the spin-orbit splitting energy L1SO to parts of the visible spectrum. Ideally it is best if L1SO is less than or equal to Eg, as this ensures efficient absorption.

For example, it may be desirable to have the percentage of atoms of Bismuth to atoms of As in the active material is around 10.5% or less such that the band gap Eg of the material is in the range of from approximately o.8 to 1.4 eV and the spin-orbit splitting energy L1SO of the material is in the range of from 0.3 to o.8 eV. This is equivalent to ranges for x in Formula 1 of o:::;x:::; o.15.

In some embodiments, it is desirable to have the percentage of atoms of Bismuth to atoms of As in the active material to be between 5 and 7%, such that the band gap Eg of the material is in the range of from approximately 1 to 1.1 eV and the spin-orbit splitting energy L1SO of the material is in the range of from o.6 to 0.7 eV. This is equivalent to ranges for x in Formula 1 of o.05:::;x:::;o.07.

FIG. 5 shows the predicted band gap of GaAsBiN on GaAs as a function of Bi and compositions at 300 K. The shaded region indicates where L1SO is greater than or equal to Eg.

It is shown that the quaternary alloys cover a wide energy range from 0.2 eV to 1.4 eV, i.e., covering the near and midinfrared, for Bi up to 12% and N up to 6%. For such a range, the strain of GaAsBiN on GaAs, however, is within i.5% (as shown in the inset of FIG. 6). The small strain of GaAs—BiN alloys on GaAs is due to strain compensation between GaAsN and GaAsBi. As relatively smaller N atoms in GaAs cause tensile strain while larger Bi atoms in GaAs lead to compressive strain, hence the incorporation of both N and Bi compensate strain.

Depending on N and Bi compositions, GaAsBiN can be flexibly designed under compressive or tensile strain on GaAs, which could also be used for producing superlattice photodetectors for detection of light in the near and mid-infrared.

FIG. 6 shows the predicted band gap and spin-orbit splitting energy as a function of Bi and N compositions in GaAsBiN on GaAs at 300 K. The crossing points of L1SO=Eg at various N compositions are marked using arrows. The shaded region indicates where LiSO is greater than or equal to Eg. The inset shows the calculated strain of GaAsBiN grown on GaAs.

In addition to the strong band gap reduction caused by the incorporation of either Bi or N, FIG. 6 shows the variation of L1SO as a function of Bi composition at various N fractions. This figure clearly shows how the addition of bismuth to GaAsN causes a strong increase in L1SO. The significant increase of L1SO with increasing Bi composition is attributed to the large atomic mass of bismuth which increases the interaction between the electron spin and orbital angular momentum.

A solar cell can be made using GaAsBiN (for example grown on GaAs). Such a cell could be schematically identical to that shown in FIG. 1, but with GaAsBiN replacing the GaAsBi.

An important consideration about the alloy GaAsBiN as an active material for a solar cell is that the Bi and N cause a large decrease in band gap whilst it is only really the Bi content that controls the SO-splitting energy (as can be seen in FIG. 6).

Hence, in one example embodiment, a GaAsBiN alloy 3% Bi and 1% N (based on the amount of As) which gives an Eg of 1 eV and a L1SO of o.56 eV with an Eg(SO)=L56 eV and strain of only about 0.2%.

From FIG. 6, it will be appreciated that there are practically infinite number of combinations of the compositions (within strain limits) to create a solar cell. For example, embodiments of the invention that use GaAsBiN as an active material for a solar cell could use less than 10% Bi and less than 6% Ni based on the amount of As. Ideally it is best if L1SO is less than or equal to Eg, as this ensures efficient absorption.

By varying the amounts of Bi and N in the GaAsBiN material, active materials for solar cells can be produced with band gaps Eg in the range of from approximately o.8 to 1.4 eV and the spin-orbit splitting energies L1SO in the range of from 0.3 to o.8 eV.

Indium is another element that could be added to GaAs to produce a quaternary alloy, which in this case would be GainAsBi.

FIG. 7 shows the predicted band gap of GainAsBi on InP as a function of Bi and In compositions at 300 K. The shaded region indicates where L1SO is greater than or equal to Eg. FIG. 8 shows the predicted band gap and spin-orbit splitting energy as a function of Bi and In compositions in GainAsBi on InP at 300 K.

Unlike GaAsBi or GaAsBiN, high quality GainAsBi cannot be grown pseudomorphically on GaAs due to excessive strain causing dislocations. However, it can be grown on an InP substrate.

For example, in such GainAsBi alloys, the amount of Bi could be 5% or less, with the amount of In ranging from 30 to 60% based on the amount of As. Ideally it is best if LiSO is less than or equal to Eg, as this ensures efficient absorption.

Compared to GaAsBi or GaAsBiN, it is possible that a GainAsBi alloy may be less suited to solar cells because it mainly covers band gaps in the mid-IR and is on a more expensive InP substrate. However, it is noted that it is possible to use InP substrates to grow GainAsBi, and then remove the InP substrate to leave a thin film cell (the InP substrate is then re-used).

One potential application for GainAsBi cells is in thermo-photovoltaics for turning waste heat into electrical energy for which efficient absorption at mid-infrared wavelengths is desirable.

In general terms, embodiments of the invention can provide a solar cell device having an active region comprising a III-V material including Bismuth and one or more other group V elements, such that the band gap energy of the material is in the range of from 0.4 to 1.4 eV and the spin-orbit splitting energy of the material is in the range of from 0.3 to o.8 eV. In some embodiments, the spin-orbit splitting energy is less than the band gap energy, and the percentage of atoms of Bismuth to atoms of the other group V elements in the material is less than around 11.5%.

Although the above mentioned embodiments of the invention relate to a solar cell, it will be appreciated that active materials according to embodiments of the invention could be used for other light detecting semiconductor devices such as photodetectors.

While the efficiency of a solar cell will be increased by maximising the wavelengths of solar light absorbed by the cell, the efficiency of a photodetector is typically measured by how well the photodetector absorbs one particular wavelength or range of wavelengths.

As discussed above, for GaAsBi based alloys, the band gap Eg and L1SO vary depending on the amount of Bi. It is possible to arrange for the band gap Eg and L1SO to be substantially equal, thus providing a very efficient photodetector at the wavelength corresponding to the band gap Eg.

For example, for GaAsBi based alloys, if the content of Bi is in the range of 9-11% of the As, then the difference between the band gap Eg and SO will be small. If the content of Bi is in the range of 9-11%, the band gap Eg and SO will be in the range of 0.7 to 0.9 eV.

From FIG. 3, it can be seen that for GaAsBi the band gap Eg and SO will be equal having a value of approximately o.8 eV when Bi is at 10.5% (+/−1%), corresponding to a wavelength of 155 onm. This wavelength is particularly important for applications in telecommunications owing to the minimum absorption loss of silica optical fibres at tis wavelength. Therefore high efficiency photodetectors at the wavelength are highly desirable.

As discussed above, FIG. 6 shows the predicted band gap and spin-orbit splitting energy as a function of Bi and N compositions in GaAsBiN on GaAs at 300 K.

From this figure, it is apparent that there are many values of percentages of Bi and Ni that lead to the band gap Eg and SO being equal.

For example, embodiments of the invention that use GaAsBiN as an active material for a solar cell could use 3 to 10% Bi and less than 6%N based on the amount of As. Ideally it is best if SO is equal to Eg, as this ensures efficient absorption for the photodetector. In some embodiments, SO can be within 10% of Eg, more preferable within 5% of Eg.

By varying the amounts of Bi and N in the GaAsBiN material, active materials for detectors can be produced with band gaps Eg and spin-orbit splitting energies SO being substantially equal in the range of from 0.3 to 0.9 eV.

Some embodiments of the invention that use GaAsBiN as an active material for a photodetector could use 5 to 7% Bi and 2 to 4% Ni based on the amount of As.

For example, for a GaAsBiN photodetector grown on GaAs targeting a wavelength of 2 μm a preferred embodiment could incorporate 6% Bismuth and 3% Nitrogen.

As for solar cells, Indium is another element that could be added to GaAsBi to produce a quaternary alloy, which in this case would be GainAsBi.

Unlike GaAsBi or GaAsBiN, GainAsBi cannot easily be grown on GaAs due to excessive strain causing dislocations. However, it can be grown on an InP substrate

For example, in such GainAsBi alloys, the amount of Bi could be 2 to 6%, with the amount of In ranging being less than 60% based on the amount of As. Ideally it is best if L1SO is equal to Eg, as this ensures most efficient photodetector absorption.

The preferred In and Bi composition pairs are given in FIG. 8, where the values corresponding to Eg=LiSO are preferred.

Some embodiments of the invention that use GainAsBi as an active material for a photodetector could use 2 to 4% Bi and 51 to 55% In based on the amount of As. Such active materials for detectors can be produced with band gaps Eg and spin-orbit splitting energies L1SO being substantially equal in the range of from 0.5 to o.6 eV.

For example, for a photodetector grown on InP targeting a wavelength of 2.3 μm, a preferred embodiment could incorporate 3% Bismuth and 53% Indium.

In general terms, embodiments of the invention can provide a light recieving semiconductor device having an active region comprising a III-V material including

Bismuth and one or more other group V elements, wherein the percentage of atoms of Bismuth to atoms of the other group V elements in the material is less than 1i.5% and is such that the spin-orbit splitting energy of the material is within 10% of the band gap energy of the material. In some embodiments, the spin-orbit splitting energy of the material is within 5% of the band gap energy of the material. In some embodiments, the spin-orbit splitting energy of the material is substantially equal to the band gap energy of the material.

In some embodiments, the spin-orbit splitting energy of the material is within 5 omeV of the band gap energy of the material.

In some embodiments, the spin-orbit splitting energy of the material is 0.3 to 1 eV.

The above mentioned embodiments of photodetectors, discuss that spin-orbit splitting energy of the material is near (e.g. within 10%) of the band gap energy of the material. This is to ensure high efficiency of the photodetector. Of course, it may be desirable to have a single photodector tuned to two different wavelengths. Applications of such detectors include sensing and differential measurements.

It will, of course, also be appreciated that broadband detection is also useful in some circumstances. In these embodiments, the detector would essentially get a boost in response at the bandgap owing to the extra absorption from the SO-HH transition.

In such embodiments, the amount of Bi (and other alloying elements) can be varied so as to give the appropriate levels of the spin-orbit splitting energy and band gap energy.

As discussed, embodiments of the invention provide a light detecting semiconductor device having an active region comprising a III-V material including Bismuth and one or more other group V elements in which the amount of Bismuth (and potentially other alloying elements) controls the levels of the spin-orbit splitting energy and band gap energy. Such devices could be, for example, a solar cell or a photodector.

In addition, to the specific materials mentioned above, there are a range of III-V materials including Bismuth that could be used. For example, similar possibilities exist when incorporating other group III and group V elements to Ga and As, of which GaAsBiB is one example. GainPBi is another example of a suitable system.

Adding nitrogen or boron to the GaAsBi allow, forming GaAsBiN or BGaAsBi, respectively, offers further means of optimising the alloy with a range of band gaps achievable with little or no strain whilst providing very high absorption as required by a solar cell or photodetector.

There are a number of III-V quaternaries that give similar possibilities.

In addition, some embodiments can use 5-component alloys. These have more flexibility but are hard to control. The use of ternaries and quaternaries is preferred in some embodiments due to the ease of control. The key element in every case is Bismuth, as it is this is what enhances the spin-orbit splitting.

The above mentioned embodiments relate to a III-V material including Bismuth and one or more other group V elements. In some embodiments, Antimony could be used in place of Bismuth. FIG. 9 shows the predicted variation in spin-orbit splitting energy as a function of group V atomic number for III-V compounds.

From FIG. 9 it is apparent that that GaAs has a predicted spin-orbit splitting energy ofless than 400 meV, that GaSb has a predicted spin-orbit splitting energy of around 750 meV, and that GaBi has a predicted spin-orbit splitting energy of around 2000 meV. It is also apparent from this figure that the affect on the spin-orbit splitting to energy comes from the group V element in the III-V compound, rather than from the group III element. This is because it is the large mass of the group V element that affects the spin-orbit splitting energy. Hence, GaBi has a large spin-orbit splitting energy than GaSb, which has a larger spin-orbit splitting energy than GaAs.

For a GaAs Sb material, the amount of Sb will determine the spin-orbit splitting energy. Hence, embodiments of the invention can provide a light detecting semiconductor device having an active region comprising a III-V material including Antimony and one or more other group V elements in which the amount of Antimony (and potentially other alloying elements) controls the levels of the spin-orbit splitting energy and band gap energy. For example, embodiments using an active material comprising a GaAs Sb material, could use Antimony at less than 25%. Such embodiments could produce, for example, photodectors (e.g. with Eg=LiSO) in the midinfrared. Alternatively, such embodiments could produce thermovoltaic devices.

GaAsSb could be grown on a GaSb or a InAs substrate.

In addition, embodiments of the invention can provide an active material comprising a GaAsinSb material, in which the amount of In and Sb are varied to control Eg and L1SO.

Many further variations and modifications will suggest themselves to those versed in the art upon making reference to the foregoing illustrative embodiments, which are given by way of example only, and which are not intended to limit the scope of the invention, that being determined by the appended claims.

1. A photovoltaic device comprising:
having an active region comprising a III-V material including Bismuth and one or more other group V elements, a band gap energy of the material being in a range of from 0.4 to 1.4 eV and a spin-orbit splitting energy of the material being in a range of from 0.3 to 0.8 eV.

2. The photovoltaic device according to claim 1, wherein the III-V material includes Ga and As.

3. The photovoltaic device according to claim 1, wherein a percentage of atoms of Bismuth to atoms of the other group V elements in the material is less than 11.5%.

4. The photovoltaic device according to claim 1, wherein the III-V material comprises a Ga—As—Bi based material, having a formula: GaAs₁₋ₓBiₓ, wherein 0≦x≦0.15.

5. The photovoltaic device according to claim 4, wherein the band gap energy of the active material is in a range of from approximately 1 to 1.1 eV and the spin-orbit splitting energy of the material is in a range of from 0.6 to 0.7 eV, and 0.05≦x≦0.07.

6. The photovoltaic device according to claim 1, wherein the III-V material comprises a GaAsBiN based material.

7. The photovoltaic device according to claim 6, wherein the band gap energy of the active material is in a range of from approximately 0.8 to 1.4 eV and the spin-orbit splitting energy of the material is in a range of from 0.3 to 0.8 eV.

8. The photovoltaic device according to claim 6, wherein the GaAsBiN based material includes less than 10% Bi and less than 6% Ni based on the amount of As.

9. The photovoltaic device according to claim 4, wherein the III-V material is grown on a GaAs substrate or a Ge substrate.

10. The photovoltaic device according to claim 1, wherein the III-V material comprises a GaInAsBi based material.

11. The photovoltaic device according to claim 10, wherein the GaInAsBi based material includes less than 5% Bi and In ranging from 30 to 60% based on the amount of As.

12. The photovoltaic device according to claim 10, wherein the GaInAsBi based material is grown on a InP substrate.

13. A photovoltaic device comprising:
an active region comprising a III-V material including Antimony and one or more other group V elements, a band gap energy of the material being in a range of from 0.4 to 1.4 eV and a spin-orbit splitting energy of the material being in a range of from 0.3 to 0.8 eV.

14. The photovoltaic device according to claim 13, wherein a percentage of atoms of Antimony to atoms of the other group V elements in the material is less than 25%, and wherein the III-V material includes Ga and As.

15. The photovoltaic device according to claim 13, wherein the III-V material forms the active region of a single junction cell or one junction of a multijunction cell.

16. A light receiving semiconductor device comprising:
an active region comprising a III-V material including Bismuth and one or more other group V elements, such that the a spin-orbit splitting energy of the material being within 10% of a band gap energy of the material.

17. The light receiving semiconductor device according to claim 16, wherein a percentage of atoms of Bismuth to atoms of the other group V elements in the material is less than 11.5%.

18. The light receiving semiconductor device according to claim 16, wherein the III-V material includes Ga and As.

19. The light receiving semiconductor device according to claim 16, wherein the spin-orbit splitting energy of the material is within 10% of the band gap energy of the material.

20. The light receiving semiconductor device according to claim 16, wherein the spin-orbit splitting energy of the material is substantially equal to the band gap energy of the material.

21. The light receiving semiconductor device according to claim 16, wherein the spin-orbit splitting energy is in a range of from 0.3 to 1.0 eV.

22. The light receiving semiconductor device according to claim 16, wherein the III-V material comprises a Ga—As—Bi based material, having a formula of GaAs₁₋ₓBiₓ, wherein the spin-orbit splitting energy of the material is in a range of from 0.7 to 0.9 eV, and 0.09≦x≦0.11.

23. The light receiving semiconductor device according to claim 16, wherein the III-V material comprises a GaAsBiN based material.

24. The light receiving semiconductor device according to claim 23, wherein the band gap energy of the active material is in a range of from approximately 0.3 to 0.9 eV, and the GaAsBiN based material includes 3 to 10% Bi and less than 6% Ni based on an amount of As.

25. The light receiving semiconductor device according to claim 16, wherein the III-V material is grown on a GaAs substrate or a Ge substrate.

26. The light receiving semiconductor device according to claim 16, wherein the III-V material comprises a GaInAsBi based material.

27. The light receiving semiconductor device according to claim 26, wherein the GaInAsBi based material includes 2 to 4% Bi and In ranging from 51 to 55% based on the amount of As, and having a spin-orbit splitting energy in a range of from 0.5 to 0.6 eV.

28. The light receiving semiconductor device according to claim 26, wherein the GaInAsBi based material is grown on a InP substrate.

29. A light receiving semiconductor device comprising:
an active region comprising a III-V material including Antimony and one or more other group V elements, such that the a spin-orbit splitting energy of the material being within 10% of a band gap energy of the material, optionally within 5% of the band gap energy of the material.

30. The light receiving semiconductor device according to claim 29, wherein a percentage of atoms of Antimony to atoms of the other group V elements in the material is less than 25%, and wherein the III-V material includes Ga and As.

31. A light receiving semiconductor device having an active region comprising a III-V material including Bismuth and one or more other group V elements, an amount of Bismuth being controlled to produce a band gap energy of the material appropriate for absorbing light at a first wavelength and to produce a spin-orbit splitting energy of the material capable of absorbing light at a second wavelength.

32. A method of manufacturing a light receiving semiconductor device arranged to absorb light at a first wavelength and a second wavelength, the method comprising:
providing an active layer comprising a III-V material including Bismuth and one or more other group V elements; and
controlling an amount of Bismuth in the III-V material to produce a band gap energy of the material appropriate for absorbing light at a first wavelength and to produce a spin-orbit splitting energy of the material capable of absorbing light at a second wavelength.

33. A light receiving semiconductor device having an active region comprising a III-V material including Antimony and one or more other group V elements, an amount of Antimony being controlled to produce a band gap energy of the material appropriate for absorbing light at a first wavelength and to produce a spin-orbit splitting energy of the material capable of absorbing light at a second wavelength.

34. A method of manufacturing a light receiving semiconductor device arranged to absorb light at a first wavelength and a second wavelength, the method comprising:
providing an active layer comprising a III-V material including Antimony and one or more other group V elements; and
controlling an amount of Antimony in the III-V material to produce a band gap energy of the material appropriate for absorb light at the first wavelength and to produce a spin-orbit splitting energy of the material capable of absorbing light at the second wavelength.

35. The photovoltaic device according to claim 8, wherein the GaAsBiN based material includes from 2 to 4% Bi and from 0.5 to 1.5% Ni based on the amount of As.

36. The light receiving semiconductor device according to claim 24, wherein the GaAsBiN based material includes from 2 to 4% Bi and from 0.5 to 1.5% Ni based on the amount of As.

37. The light receiving semiconductor device according to claim 24, wherein the GaAsBiN based material includes from 5 to 7% Bi and from 2 to 4% Ni based on the amount of As.

38. The light receiving semiconductor device according to claim 29, wherein the spin-orbit splitting energy of the material within 5% of the band gap energy of the material.
